(19) United States
(12) Patent Application Publication
(10) Pub. No.: US 2026/0040632 A1
(43) Pub. Date: Feb. 5, 2026

(54) ENERGY EFFICIENT, STRAINED TOPOLOGICAL INSULATOR SPIN FIELD EFFECT TRANSISTOR (STI-SPINFET) FREQUENCY MULTIPLIER

(71) Applicant: VIRGINIA COMMONWEALTH UNIVERSITY, Richmond, VA (US)

(72) Inventor: Supriyo BANDYOPADHYAY, Glen Allen, VA (US)

(21) Appl. No.: 19/150,056

(22) PCT Filed: Feb. 2, 2024
(86) PCT No.: PCT/US2024/014144

§ 371 Date: Jul. 22, 2025

Related U.S. Application Data
(60) Provisional application No. 63/442,828, filed on Feb. 2, 2023.

(51) Int. Cl. H10D 48/00; H10N 30/20; H10N 50/20

(52) U.S. Cl. CPC H10D 48/385; H10N 30/20; H10N 50/20

(57) ABSTRACT

A three-dimensional (3D) topological insulator (Tl), configured with a surface channel for conducting spin polarized electron flow, and piezoelectric element that strains the 3D Tl, responsive to an input voltage, producing stress in the surface channel according to a voltage-to-stress characteristic (VTSC). A spin polarizer and spin analyzer act as source and drain and produce an electric field through the surface channel when a voltage is applied between the source and drain, the spin polarizer injects spin polarized electrons to flow through the surface channel and arrive at the spin analyzer as arrival electrons. The surface channel has a stress-to-rotation characteristic (STRC) that, responsive to the stress, rotates the spin polarization such that the arrival electrons have a rotated plane of polarization, at a rotation angle.

### CROSS-REFERENCE TO RELATED APPLICATIONS

This application claims priority to U.S. Provisional Application 63/442,828 filed Feb. 2, 2023, which is hereby incorporated by reference in its entirety.

### TECHNICAL FIELD

This disclosure generally relates to transistors and frequency multipliers and, more particularly, to topological insulator (TI) field effect transistor-based frequency multipliers and current modulators.

### BACKGROUND

Concepts and various structures for spin-field-effect-transistors (SPINFET) have been in the published art for several decades.

Target applications for SPINFETs, particularly during early work, included various applications for which conventional field effect transistors (FETs) were used. An anticipated advantage of relacing FETs with SPINFETs was that the latter would require a lower gate voltage (and hence lower energy) to elicit transistor operation, since, unlike conventional FETs, SPINFETs did not need to change carrier concentrations in the channels with the gate voltage. Instead, SPINFETs needed to change the spin polarization of carriers in the channels with the gate voltage. If less gate voltage was needed to change spin polarization than to change carrier concentration, then SPINFETs could become a low-power replacement for the FET devices.

In reality, SPINFETs were never shown to require less gate voltage to realize transistor operation than conventional FETs since the spin orbit interaction in most transistor materials is too weak to allow changing the spin polarization with a low gate voltage. Still another technical issue in two-dimensional SPINFETs is that ensemble averaging over the transverse wavevector degrades the conductance on/off ratio, making them unsuitable for digital applications for which conventional FETs are used.

The above technical shortcomings and issues have proved very difficult to overcome and decades of research appear unable to satisfactorily alleviate them.

### SUMMARY

Devices according to embodiments have a plurality of novel features and novel combinations of features distinguishing over and providing improvements over conventional SPINFETS. The features include, without limitation, the gate potential not modulating spin-orbit interaction to elicit transistor operation. As will be appreciated by persons having ordinary skill in the art (“PHOSITAs) after reading this disclosure in its entirety, is that transistor action by devices and methods according to various of the disclosed embodiments does not require any spin-orbit interaction. Instead, transistor action is realized by mechanically straining the channel material with a gate voltage to change the velocity of charge carriers in the channel. The channel is made of (the surface of) a three dimensional topological insulator (3D-TI) thin film with two (wavevector-dependent) spin eigenstates. The ferromagnetic source injects spins with a polarization that is a superposition of the two eigenspin states. The gate voltage mechanically strains the TI film, which modulates the Dirac velocity of the surface states, thereby changing the phase relationship in the superposition. That effectively rotates the injected spin, just as the gate voltage rotates the injected spin in the channel of a conventional SPINFET.

The ferromagnetic drain contact acts as a spin analyzer. When the spin in the channel has been rotated by the gate voltage such that it is parallel to the drain's magnetization when it arrives at the drain contact, it transmits with the highest probability (current is “on”), and if it arrives with spin antiparallel to the drain's magnetization, it transmits with the lowest probability (current is “off”).

Examples according to one or more embodiments can include, without limitation, a single-transistor low-power frequency multiplier device that can comprise, for example, a 3D TI body having a planar surface extending between a first edge and a second edge. The planar surface can provide a conducting surface channel for spin-polarized current flow, which can extend from the first edge to the second edge. Devices according such embodiments can further comprise a piezoelectric element coupled to the 3D TI body and configured to exert, responsive to an input voltage, one or more mechanical forces on the 3D TI body in a manner producing a corresponding mechanical stress in the surface channel. a spin polarizer adjacent the first edge and a spin analyzer adjacent the second edge, mutually configured to produce, in response to respective biasing voltages, an electric field extending into the first edge, through the surface channel and out the second edge, wherein the spin polarizer is further configured to inject, based at least in part on the electric field, spin polarized electrons onto the planar surface. In accordance with such one or more embodiments, surface channel can be further configured to conduct a flow, urged by the electric field, of the spin polarized electrons from the first edge to arrive at the second edge as arrival spin polarized electrons, and to rotate the spin polarization of the electrons, during the flow, via a mechanical stress generated in by the input voltage applied to the piezoelectric element, resulting in the arrival spin polarized electrons having a rotated plane of spin polarization, with the amount of rotation depending on the input voltage. Also according to such one or more embodiments, the spin analyzer can be configured to pass only a fraction of the arrival spin polarized electrons, with the fraction depending on the angle of rotation, as electric output current whose magnitude depends on the angle of rotation and hence the input voltage, resulting in the output current having an oscillatory dependence on the input voltage, in accordance with an oscillatory output current versus input voltage transfer characteristic. In devices according to various embodiments, the oscillatory output current versus input voltage transfer characteristic has a period, the period being a voltage difference between a first voltage level of the input voltage, at which the angle of rotation is a theta value, and a second voltage level of the input voltage, at which the angle of rotation is again the theta value. In oscillatory output current versus input voltage transfer characteristic, devices according to such embodiments can provide, responsive to an oscillating input voltage, oscillating at an input frequency, having an amplitude equal to a difference between the first voltage and the second voltage, the output current can oscillate, with a frequency higher than the input frequency, producing a frequency multiplication by a frequency multiplication factor, and the frequency multiplication factor is twice the ratio of the amplitude of the input voltage to the period of the transfer characteristic.

Apparatuses according to various further embodiments, can include, for example, an STI-SPINFET based oscillatory transfer characteristic voltage-to-current device, which can comprise a 3D TI body, having a conducting surface channel that extends a length from a first edge to a second edge of a planar surface, providing for spin polarized electron flow, and having a stress-to-rotation (STR) characteristic that during the flow, responsive to a level of a mechanical stress, rotates the polarization plane of the spin polarized electrons. The example devices can further comprise a piezoelectric element coupled to the 3D TI body and configured to mechanically strain the 3D TI body, responsive to an input voltage, in a manner producing the mechanical stress at a stress level according to a voltage-to-stress (VTS) characteristic, providing a voltage-to-rotation (VTR) characteristic based on the VTS and the STR characteristics. In accordance with various embodiments, the example devices can further comprise a spin polarizer adjacent the first edge and a spin analyzer adjacent the second edge, mutually configured to produce, responsive to respective biasing voltages, an electric field extending into the first edge, through the conducting surface channel and out the second edge. According to one or more embodiments the spin polarizer can be further configured to inject, responsive to the electric field, spin polarized electrons onto the planar surface, initiating flow of the spin polarized electrons through the conducting surface channel to arrive at the second edge as arrival spin polarized electrons, the polarization plane of the arrival spin polarized electrons being rotated by a rotation angle ⊖ in accordance with the input voltage and the VTR characteristic. Further, in example devices according to one or more embodiments the piezoelectric element and the 3D TI body can be further mutually configured such that the VTR characteristic is oscillatory, rotating ⊖ more than one cycle in response to increasing the input voltage from a first level to a second level, and the spin analyzer can be further configured to pass only a fraction of the arrival spin polarized electrons, as an output current, the fraction and therefore the output current depending on ⊖, converting the oscillatory VTR characteristic to an oscillatory voltage-to-current (VTC) transfer characteristic.

This Summary identifies example features and aspects and is not an exclusive or exhaustive description of disclosed subject matter. Whether features or aspects are included in or omitted from this Summary is not intended as indicative of relative importance of such features or aspects. Additional features are described, explicitly and implicitly, as will be understood by persons of skill in the pertinent arts upon reading the following detailed description and viewing the drawings, which form a part thereof.

### BRIEF DESCRIPTION OF THE DRAWINGS

FIG. 1A shows a perspective view of one three-dimensional model of one example configuration and geometric form of one energy efficient, strained topological insulator spin field effect (STI-SPINFET) device according to one or more embodiments; FIG. 1A shows a cross-section view of certain internal structural features of the FIG. 1A example configuration, from FIG. 1A cross-cut plane 1B-1B; and FIG. 1C shows a cross-section view of certain other internal structural features of the FIG. 1A example configuration, from FIG. 1A cross-cut plane 1C-1C;

FIG. 2 shows an enlarged view of FIG. 1B area “AA;

FIG. 3 shown a graphic model of a surface of a topological insulator (TI) body in accordance with one or more embodiments, such the FIG. 1A-1C example configuration, that can function as a channel of the embodiments' STI-SPINFET, in an arrangement with two example spin-polarized ferromagnetic contacts, each magnetized in the direction of current flow, to function as a source and a drain;

FIG. 4 shows an energy vs. wave vector graph representing energy dispersion relations of spin split bands on surface of a TI body, using example materials such as Bi2Se3 or Bi2Te3; and

FIG. 5 shows a combination gate voltage vs. conductance transfer characteristic graph and gate voltage vs. channel stress characteristic graph of an STI-SPINFET device according to one or more embodiments, at two example channel widths.

### DETAILED DESCRIPTION

Configurations of devices according to one or more embodiments, through a combination of a particularly structured three dimensional (3D) topological insulator (TI) body, supporting a first and a second conducting element, particularly structured and arranged, with the TI body mechanically coupled to a particular configured voltage-to-strain application mechanism, such as a specifically configured piezoelectric element, provide a novel, multiple feature, multiple utility voltage to current transfer device that in turn provide various improvements to the SPINFET technology, and to other technologies including, without limitation, the technology field of low power frequency multipliers.

In configuration according to one or more embodiments the 3D TI body can have geometry that includes a planar surface extending having a conducting surface channel that extends a length from a first edge to a second edge of a planar surface, providing for spin polarized electron flow, and having a stress-to-rotation (STR) characteristic that during the flow, responsive to a level of a mechanical stress, rotates the polarization plane of the spin polarized electrons. An example configuration further comprises a piezoelectric element coupled to the 3D TI body and configured to mechanically strain the 3D TI body, responsive to an input voltage, in a manner producing the mechanical stress at a stress level according to a voltage-to-stress (VTS) characteristic. As described in more detail in later sections, the VTS characteristic, in combination or in tandem with the STR characteristic of the conducting surface channel, provide a voltage-to-rotation (VTR) characteristic.

According to one or more embodiments, configuration can further comprise a spin polarizer arranges adjacent the first edge and a spin analyzer adjacent the second edge, mutually arranged and configured to produce, responsive to respective biasing voltages, an electric field extending into the first edge, through the conducting surface channel and out the second edge. According to various embodiments, the spin polarizer can be further configured to inject, responsive to the electric field, spin polarized electrons onto the planar surface. As describe in more detail in later sections, in accordance with one or more embodiments, the injection initiates a flow of the spin polarized electrons through the conducting surface channel to arrive at the second edge as arrival spin polarized electrons. The conducting channel, because of the input voltage induced stress, rotates the polarization plane of the electron as identified above, causing the arrival electrons have a rotation angle ⊖ in accordance with the input voltage and the VTR characteristic.

According to various embodiments, the spin analyzer is further configured to pass only a fraction of the arrival spin polarized electrons, as an output current, the fraction and therefore the output current depending on ⊖. Further according to one or more embodiments, the piezoelectric element and the 3D TI body can be further configured, in a mutual manner, such that the VTR characteristic causes ⊖ to rotate more than one cycle in response to increasing the input voltage from a first level to a second level. This feature, combined with the polarization and corresponding ⊖ selectivity of the spin analyzer, produce an oscillatory VTR characteristic. Since the output current is dependent on the fraction of the arrival spin polarized electrons that pass through the spin analyzer, the oscillatory VTR characteristic produces an oscillatory voltage-to-current (VTC) transfer characteristic.

Preceding description has referred to a conductive surface channel at a surface of the 3D TI body, and to a spin polarizer and a spin analyzer that, respectively, inject spin polarized electrons onto the planar surface of the 3D TI body and perform a ⊖-based filtering and conversion to output current operation. The amount of ⊖ is controlled by the input voltage, through the piezoelectric element's corresponding strain operation that establish the stress in the channel. For purposes of description, the combined operation of the piezoelectric element in response to the input voltage, and the spin analyzer's filtering operation will be alternatively referred to as a “gate” operation, by which the input voltage modulates the output current. Also, the respective spin polarized electron injecting function of the spin polarizer and the arrival electron-to-output current conversion function of the spin analyzer will be alternatively referred to as “source” and “drain” operations. It will be understood that this disclosure's alternative use of the terms gate, source, and drain, as identified above, is for convenience of description and for viewing certain aspects of the STI-SPINFET device's operation in terms of conventional FET operations.

It will be understood that in accordance with the various embodiments the gate potential does not modulate spin-orbit interaction. In fact, spin-orbit interaction is not needed for transistor action at all. The channel is made of (the surface of) a three dimensional topological insulator (3D-TI) thin film with two (wavevector-dependent) spin eigenstates. The ferromagnetic source injects spins with a polarization that is a superposition of the two eigenspin states. The gate voltage mechanically strains the TI film, which modulates the Dirac velocity of the surface states, thereby changing the phase relationship in the superposition. That effectively rotates the injected spin, just as the gate voltage rotates the injected spin in the channel of a conventional SPINFET.

The ferromagnetic drain contact acts as a spin analyzer, just as in a conventional SPINFET. When the spin in the channel has been rotated by the gate voltage such that it is parallel to the drain's magnetization when it arrives at the drain contact, it transmits with the highest probability (current is “on”), and if it arrives with spin antiparallel to the drain's magnetization, it transmits with the lowest probability (current is “off”). Thus, a transistor action is realized, differing from the conventional SPINFET by spin rotation being achieved via strain-induced modulation of the Dirac velocity in the TI surface, as opposed to modulation of spin-orbit interaction.

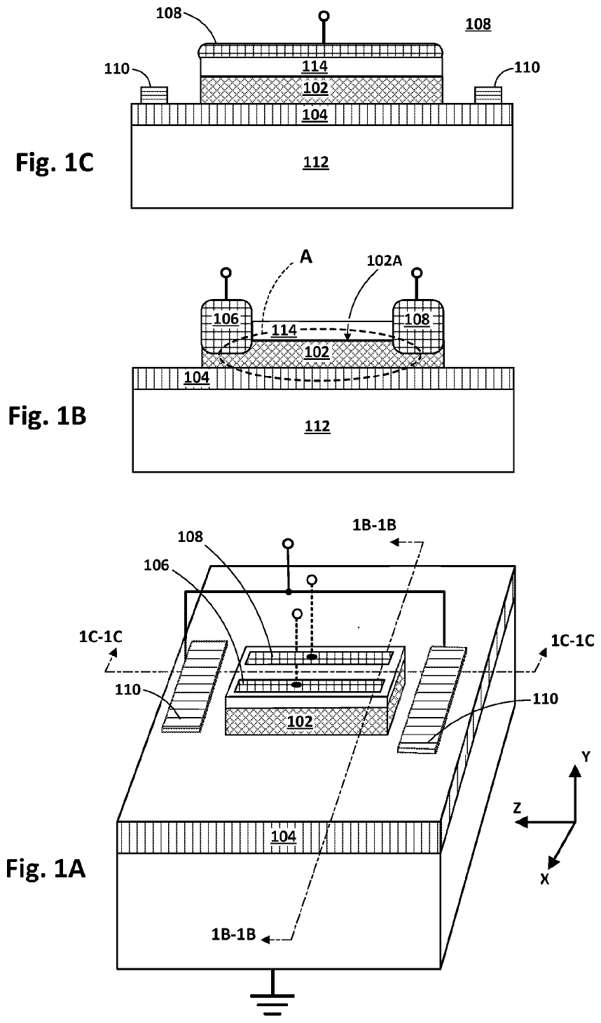

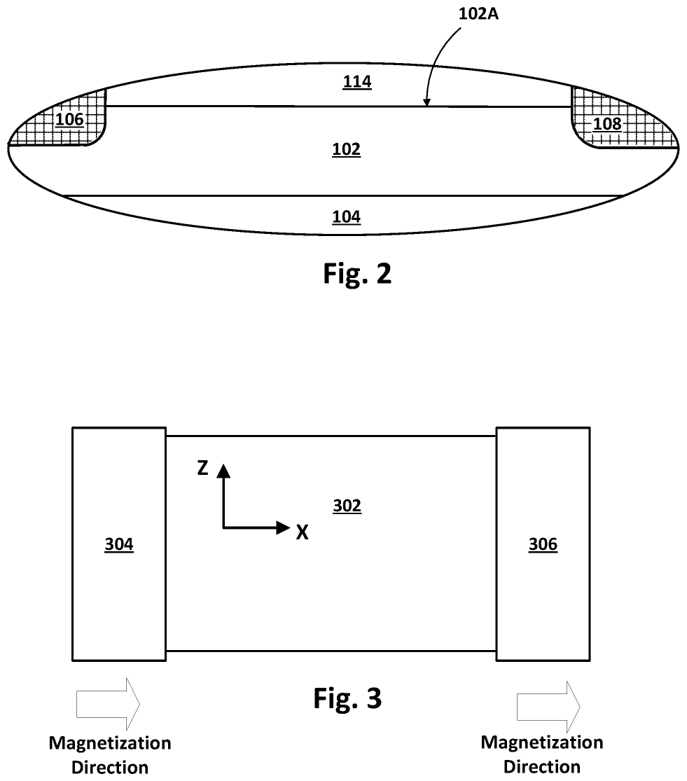

FIG. 1A shows a perspective view of one three-dimensional model of one example configuration 100 and geometric form of one energy efficient STI-SPINFET) device according to one or more embodiments. The example 100 includes a 3D TI body 102 supported on, e.g., in a secured to or otherwise mechanically coupled to manner, a piezoelectric element 104. The piezoelectric element 104 can be, according to one or more embodiments, a piezoelectric film. To avoid introducing another reference number for the film configuration of the piezoelectric element 104, it will be alternatively referenced as the “piezoelectric film 104.”

The 3D TI body 102 can be configured with an upper surface 102A configured to support a particular arrangement of a first conductive element 106, configured to function as a spin polarizer, and therefore alternatively referred to as “spin polarizer 106,” and a second conductive element 108 configured to function as a spin analyzer polarizer and therefore alternatively referred to as “spin analyzer 106.” According to one or more embodiments, the portion of the upper surface 102A extending between an inward face of the spin polarizer 106 and the facing inward face of the spin analyzer 108 is preferably planar. That portion will therefore be alternative referenced, for purposes of this description, as “planar surface 102A.” In accordance with known theory of topological insulators, the planar surface 102A can function as a conductive surface channel for conducting a flow of spin polarized electrons. For convenience to the reader, this disclosure provides descriptions of various portions of such theory.

Referring to FIGS. 1A-1C, in accordance with one or more embodiments, disposed on and electrically coupled to the vertically poled thin piezoelectric film 104 can be two mutually shorted electrodes 110. The shorted pair of electrodes 110 can act as a gate. This gate configuration generates strain in an intervening region of the piezoelectric, i.e., underneath the 3D-TI film 102. The generation of strain, itself, is in accordance with piezoelectric technology known to persons having ordinary skill in the art (“PHOSITAs).” The combination of such piezoelectric strain, with the 3D TI body, the spin polarizer and the spin analyzer in accordance with disclosed embodiments, though, is novel.

If the input gate voltage whose polarity is such that the resulting (vertical) electric field is directed opposite to the direction of poling, then compressive stress will be generated along the line joining the two electrodes (z-axis in FIG. 1A) and tensile stress in the perpendicular direction (x-axis). Reversing the polarity will reverse the signs of the stresses. The use of a piezoelectric thin film deposited on a conducting substrate, as opposed to a piezoelectric substrate, is dictated by the fact that piezoelectrics are insulators and hence a much larger voltage would have been needed to generate a given strain had we substituted the piezoelectric film with a piezoelectric substrate. As long as the piezoelectric film thickness is much larger than the thickness of the TI film, we can assume that 100% of the strain generated in the piezoelectric is transferred to the TI film. The transferred stress/strain changes the energy dispersion relation of the surface states in the 3D-TI, specifically the slope, and hence the Dirac velocity. This results in spin rotation in the TI surface, i.e., the transistor channel, which in turn modulates the current flowing between the ferromagnetic source 106 and drain 108.

Functionality of the thin insulating layer 114 between the ferromagnetic source/drain contacts and the TI surface (see FIGS. 1A-1C) can include acting as a tunnel barrier. The thin insulating layer 114 can, for example, utilize thin insulating layers as used in conventional SPINFET technology to improve spin injection and detection efficiencies of source/drain contacts.

Regarding materials for the spin polarizer 106 and spin analyzer 108, these can be ferromagnetic contact materials, for example but not limited to, such materials that have with a high degree of spin polarization, e.g., half metals, to further increase the spin injection/detection efficiency.

Because the device is two-dimensional, ensemble averaging over the transverse wave vector kz inevitably dilutes the current modulation, very much like the original two-dimensional SPINFET, resulting in very poor on/off ratio for the channel conductance. That precludes any use as a switch, but there can be other uses, such as in frequency multiplication, as we discuss later.

### Considerations in Selecting Materials and Component Geometries

For the TI layer considerations for selection of its material include change of Dirac velocity with respect to stress in the Γ-K̅ crystallographic direction. In Bi₂Se₃, the Dirac velocity in the Γ-K̅ crystallographic direction is ˜6.2×10⁵ m/s under no stress and increases linearly with compressive stress by ˜2×10⁴ m/s per GPa. Therefore, this material is a good choice for the TI.

For the piezoelectric layer, considerations for selection of its material include compatibility with the material selected for the TI, including compatibility of processing. For example, one currently used growth temperature range for TI comprises temperatures in the range of 400°-500° Celsius. There are recent reports of perovskites such as, for example, like (1−x)BiScO₃-xPbTiO₃ which can survive temperatures up to 460° C. and hence would be compatible with TI growth. It has a d₃₁ value of −670 pC/N and therefore is a good choice. With this d₃₁ value, one can generate a strain & of 1000 ppm in the piezoelectric with an electric field E of 1.5 MV/m which is a very reasonable electric field (ε=d₃₁ ε).

Regarding relative thickness of the TI layer and the piezoelectric layer, it is preferable that the TI film is much thinner than the piezoelectric film.

Technical publications recite the Young's modulus of Bi₂Se₃ nanoribbons as ˜40 GPa and that can be assumed, e.g., know-how regarding TI behavior that the inventor believes to be possessed by PHOSITAs, to be about the same in thin film Bi₂Se₃. Hence the stress generated by a strain of 1000 ppm in Bi₂Se₃ is 40 MPa. This stress will increase the Dirac velocity v₀ in Bi₂Se₃ from 6.2×10⁵ m/s to 6.2×10⁵+800 m/s, which is enough to modulate the channel conductance of the transistor between the maximum and minimum values. Thus the material used was (1−x)BiScO₃-xPbTiO₃ for the piezoelectric and Bi₂Se₃ for the TI.

Without being bound to theory, FIG. 3 shows one representative high level graphical model 300, showing a modeled conducting surface 302 of the 3D-TI (the channel) pinched between a modeled ferromagnetic source contact 304 and a modeled ferromagnetic drain contact 306. Description assumes TI is a common material, e.g., Bi2Te3 or Bi2Se3. Applying, e.g., from conventional TI design and analysis techniques, Hamiltonian describing the surface states near a Dirac point (including higher order terms in the wave vector, up to third order) is σ.

$${H}_{T I} = \frac{{ℏ}^{2}}{2 {m}^{*}} ( {k}_{x}^{2} + {k}_{z}^{2} ) + ℏ {v}_{k} ( {k}_{x} {σ}_{z} - {k}_{z} {σ}_{x} ) + \frac{λ}{2} {ℏ}^{3} ( {k}_{+}^{3} + {k}_{-}^{3} ) {σ}_{y} , \qquad Eqn . ( 1 )$$

where
   m* is the effective mass,
   λ is the band warping factor,

$${v}_{k} = {v}_{0} ( 1 + α {k}^{2} ) , \qquad Eqn . ( 1 A )$$

$${k}^{\pm } = {k}_{x} \pm i {k}_{z} , \qquad Eqn . ( 1 B )$$

v₀ is v0 is the Dirac velocity, and
σx, σy, and σz are the Pauli spin matrices.

To avoid obfuscation with unnecessary mathematical details, we omit band warping and the second order correction to the Dirac velocity (i.e., α=λ=0), which reduces the Hamiltonian to

$${H}_{T I} = \frac{{ℏ}^{2}}{2 {m}^{*}} ( {k}_{x}^{2} + {k}_{x}^{2} ) + ℏ {v}_{0} ( {k}_{x} {σ}_{z} - {k}_{z} {σ}_{x} ) \qquad Eqn . ( 2 )$$

The Hamiltonian in Equation (2) omits, for reasons as above, the effect of finite thickness and width, as well as any external magnetic field or spin-orbit interaction.

Diagonalizing the Hamiltonian yields the energy dispersion relation of spin resolved states as

$${E}_{\pm } = \frac{{ℏ}^{2} {k}^{2}}{2 {m}^{*}} \pm {ℏν}_{0} k , \qquad Eqn . ( 3 )$$

$$wherein , k = \sqrt{{k}_{x}^{2} + {k}_{z}^{2}} \qquad Eqn . ( 4 )$$

In an “ideal” topological insulator (TI) surface, only the second term in the Hamiltonian in Equation (2) will be present, and therefore the ideal TI surface energy dispersion relation can be familiar Dirac cones, according to Equation (5)

$$E = \pm ℏ {v}_{0} k \qquad Eqn . ( 5 )$$

Real TI materials, though, for example, Bi₂Se₃, do not fit this bill and therefore the first term in the Hamiltonian will also be present. However, said term will be much smaller than the second term.

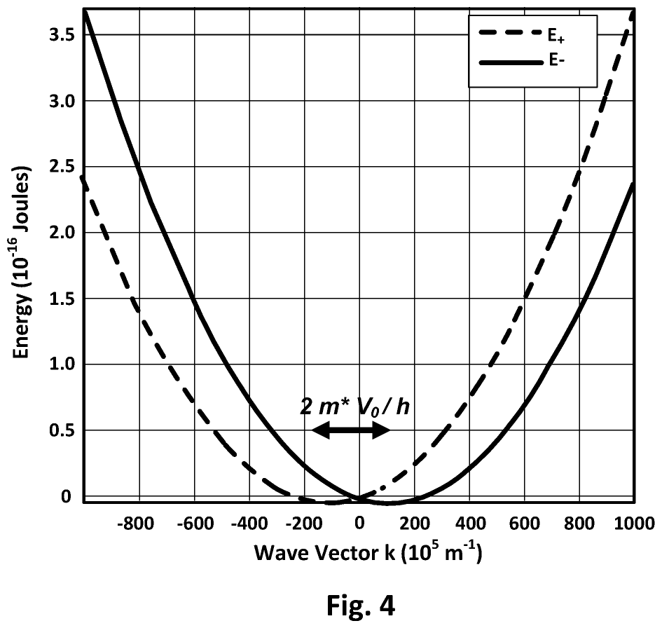

FIG. 4 shows a plot of the dispersion relations in Equation (2) using an m* value of 0.2 m₀ and a v₀ value of 6.2×10⁵ m/s where m₀ is the free electron mass, and these numeric values, for purposes of example, are characteristic of Bi₂Se₃.

The eigenspinors of the Equation (2) Hamiltonian can be described according to Equation (6), as

$${ψ}_{+} = [ \begin{matrix}sin θ \\ cos θ\end{matrix} ] ; {ψ}_{-} = [ \begin{matrix}- cos θ \\ sin θ\end{matrix} ] \qquad Eqn . ( 6 )$$

$$where$$

$$θ = ( \frac{1}{2} ) arctan ( \frac{{k}_{z}}{{k}_{z}} ) \qquad Eqn . ( 6 A )$$

The TI film can be assumed as semi-infinite in the z-direction, in which case, the wave vector component k_{z} is a good quantum number. Looking at Equation (2), it can be seen that for any given energy E and magnitude of the wave vector component k_{z}, the magnitudes of the x-components of the wave vectors are different in the two spin resolved states. Their relation can be described by the following Equation (7):

$$E = \frac{{ℏ}^{2} [ {\vert {k}_{X}^{+} \vert}^{2} + {\vert {k}_{Z} \vert}^{2} ]}{2 {m}^{*}} + ℏ {v}_{0} \sqrt{{\vert {k}_{X}^{+} \vert}^{2} + {\vert {k}_{Z} \vert}^{2}} \qquad Eqn . ( 7 )$$

$$E = \frac{{ℏ}^{2} [ {\vert {k}_{X}^{-} \vert}^{2} + {\vert {k}_{Z} \vert}^{2} ]}{2 {m}^{*}} - ℏ {v}_{0} \sqrt{{\vert {k}_{X}^{-} \vert}^{2} + {\vert {k}_{Z} \vert}^{2}}$$

Hence the angle ⊖ in Equation (6) is different in the two spin resolved states for any given energy E and |k_{z}|. We will call them θ⁺ and θ⁻, where

$${θ}^{\pm } = ( \frac{1}{2} ) arctan ( \frac{{k}_{z}}{{k}_{x}^{\pm }} ) . \qquad Eqn . ( 8 )$$

Therefore, we can rewrite Equation (6) as Equation (9), as below:

$${ψ}_{+} = [ \begin{matrix}sin {θ}^{+} \\ cos {θ}^{+}\end{matrix} ] ; {ψ}_{-} = [ \begin{matrix}- cos {θ}^{-} \\ sin {θ}^{-}\end{matrix} ] \qquad Eqn . ( 9 )$$

The inequality between θ⁺ and θ⁻ is a consequence of the parabolic term in Equation (2) or (3), which can be assumed as present but, in present TI material technologies the magnitude is small. It will be understood that without that term, the relation between

$${k}_{x}^{+} and {k}_{x}^{-}$$

can be described by Equation (10) and relation between θ⁺ and θ⁻ can be described by Equation (11), for any given k_{z}:

$${k}_{x}^{+} = \pm {k}_{x}^{-} \qquad Eqn . ( 10 )$$

$${θ}^{+} = \pm {θ}^{-} for any given {k}_{z} . \qquad Eqn . ( 11 )$$

For purposes of description, it will be assumed that the ferromagnetic source contact 304 and the ferromagnetic drain contact 306 contacts are both magnetized in the +x-axis direction shown in FIG. 3. We will assume that the source injects only +x-polarized spins into the TI at the complete exclusion of −x polarized spins (perfect spin polarizer). This assumption can be relaxed, but description of such is omitted to avoid obfuscation of the invention concepts by analytical detail not necessary for practicing according to the various embodiments and which a PHOSITA, upon reading this this disclosure in its entirety, can readily perform if so desired.

An injected +x-polarized spin from the source contact 306 will couple into the two eigenspin states ψ₊ and ψ₋ in the channel (TI surface) 302 with wavevector dependent coupling coefficients C⁺ and C⁻. We can describe this occurrence as the incident +x-polarized beam splitting into two beams, each corresponding to an eigenspinor in the TI channel 302. These two beams propagate in different directions since

$${k}_{x}^{+} \neq {k}_{x}^{-}$$

for any given energy and k_{z}. This behavior of the TI channel 302 can be compared, for purposes of description, to that of a birefringent medium. Also, the beam splitting can be expressed according to the following Equation (12):

$${\underbrace{\frac{1}{\sqrt{2}} [ \begin{matrix}1 \\ 1\end{matrix} ]}}_{+ x - pola r i z e d} = {C}^{+} {ψ}^{+} + {C}^{-} {ψ}^{-} = {C}^{+} [ \begin{matrix}sin {θ}^{+} \\ cos {θ}^{+}\end{matrix} ] + {C}^{-} [ \begin{matrix}- cos {θ}^{-} \\ sin {θ}^{-}\end{matrix} ] \qquad Eqn . ( 12 )$$

The coupling coefficients in Eqn. (12) can be described by Equations (13) and (14) below:

$${C}^{+} = {C}^{+} ( {k}_{z} , {k}_{x}^{+} , {k}_{x}^{-} ) = \frac{sin ( {θ}^{-} + \frac{π}{4} )}{cos ( {θ}^{+} - {θ}^{-} )} \qquad Eqn . ( 13 )$$

$${C}^{-} = {C}^{-} ( {k}_{z} , {k}_{x}^{+} , {k}_{x}^{-} ) = - \frac{cos ( {θ}^{+} + \frac{π}{4} )}{cos ( {θ}^{+} - {θ}^{-} )} \qquad Eqn . ( 14 )$$

In the drain contact 306 (i.e., the spin analyzer), the two beams can interfere. The phase difference between them, which is accrued in traversing the channel, will determine the spinor (and hence the spin polarization) of the arrival electrons impinging on the drain 306. This, in turn, determines the transmission probability, i.e., the fraction of the arrival spin electrons that pass through the drain contact 306 (i.e., the spin analyzer) and therefore the source-to-drain current.

In accordance with various embodiments, the phase difference the spin polarization of the arrival electrons and the polarization can be altered by the voltage input which, applied to the piezoelectric film 104 via the electrodes 110, strains the 3D TI body 102 which modifies or modulates the Dirac velocity, in turn modifies or modulates the rotation, thus eliciting the transistor functionality.

Referring to FIG. 3, the spinor at the drain end, i.e., the spin analyzer 306, will be references as Ψ, as set forth in the following Equation (15), and its rewritten form Equation (16)

$${[ Ψ ]}_{d r a i n} = {C}^{+} [ \frac{sin {θ}^{+}}{cos {θ}^{+}} ] {e}^{i ( {k}_{x}^{+} l + {k}_{Z} W )} + {C}^{-} [ \frac{- cos {θ}^{-}}{sin {θ}^{-}} ] {e}^{i ( {k}_{x}^{-} l + {k}_{Z} W )} \qquad Eqn . ( 15 )$$

$${[ Ψ ]}_{-} drain = \frac{sin ( {θ}^{-} + \frac{π}{4}}{cos ( {θ}^{+} - {θ}^{-} )} [ \frac{sin {θ}^{+}}{cos {θ}^{+}} ] {e}^{i ( {k}_{x}^{+} l + {k}_{Z} W )} - \frac{cos ( {θ}^{+} + \frac{π}{4}}{cos ( {θ}^{+} - {θ}^{-} )} [ \frac{- cos {θ}^{-}}{sin {θ}^{-}} ] {e}^{l ( {k}_{x}^{-} l + {k}_{Z} W )} \qquad Eqn . ( 16 )$$

where L is the channel length (distance between source and drain contacts) and W is the transverse displacement of the electron as it traverses the channel.

The transmission amplitude t, as represented in the following Equation (17), is the projection of the arriving spinor on the polarization of the spin analyzer 306, which is labeled on FIG. 3 as the +x-polarization. Equation (17) does not model multiple reflection effects, as estimation as consistency between Equation (17) and test measurements indicates such effects insignificant. For purposes of description Equation (17) is re-written as Equation (18) and as Equation (19):

$$t = \frac{1}{\sqrt{2}} {e}^{i {k}_{Z} W} \frac{sin ( {θ}^{-} + \frac{π}{4}}{cos ( {θ}^{+} - {θ}^{-} )} {e}^{i {k}_{x}^{+} L} [ 11 ] [ \frac{sin {θ}^{+}}{cos {θ}^{+}} ] - \frac{1}{\sqrt{2}} {e}^{i {k}_{Z} W} \frac{cos ( {θ}^{+} + \frac{π}{4}}{cos ( {θ}^{+} - {θ}^{-} )} {e}^{i {k}_{x}^{+} L} [ 11 ] [ \frac{- cos {θ}^{-}}{sin {θ}^{-}} ] \qquad Eqn . ( 17 )$$

$$t = \frac{1}{\sqrt{2}} {e}^{i {k}_{Z} W} \frac{sin ( {θ}^{-} + \frac{π}{4}}{cos ( {θ}^{+} - {θ}^{-} )} {e}^{i {k}_{x}^{+} L} ( sin {θ}^{+} + cos {θ}^{+} ) - \frac{1}{\sqrt{2}} {e}^{i {k}_{Z} W} ( sin {θ}^{-} - cos {θ}^{-} ) \qquad Eqn . ( 18 )$$

$$t = \frac{{e}^{i {k}_{z} W}}{cos ( {θ}^{+} - {θ}^{-} )} sin ( {θ}^{-} + \frac{π}{4} ) sin ( {θ}^{+} + \frac{π}{4} ) {e}^{i {k}_{x}^{+} L} - \frac{{e}^{i {k}_{Z} W}}{cos ( {θ}^{+} - {θ}^{-} )} sin ( {θ}^{-} + \frac{π}{4} ) sin ( {θ}^{+} + \frac{π}{4} ) {e}^{i {k}_{x}^{+} L} \qquad Eqn . ( 19 )$$

The transmission probability T, which is defined by Equation (20) below, is according to Eqn. (21).

$$T = {\vert t \vert}^{2} \qquad Eqn . ( 20 )$$

$$T = {sin}^{2} ( {θ}^{-} + \frac{π}{4} ) {sin}^{2} ( {θ}^{+} + \frac{π}{4} ) + {cos}^{2} ( {θ}^{-} + \frac{π}{4} ) {cos}^{2} ( {θ}^{+} + \frac{π}{4} ) + \frac{1}{2} cos ( 2 {θ}^{-} ) cos ( 2 {θ}^{+} ) cos ∅ \qquad Eqn . ( 21 )$$

$$where$$

$$ϕ = ( {k}_{x}^{+} - {k}_{x}^{-} ) L \qquad Eqn . ( 21 A )$$

From Equation (7) above the following Equation (22) can be obtained:

$$\sqrt{{( {k}_{x}^{+} )}^{2} + {k}_{z}^{2}} - \sqrt{{( {k}_{x}^{-} )}^{2} + {k}_{z}^{2}} = - \frac{2 {m}^{*} {v}_{0}}{ℏ} \qquad Eqn . ( 22 )$$

Defining kₐᵥ according to the following Equation (23), and multiplying both sides of Equation (22) by 2kₐᵥ yields Equation (24) as follows:

$${k}_{a v} = \frac{( \sqrt{{( {k}_{x}^{+} )}^{2} + {k}_{z}^{2}} + \sqrt{{( {k}_{x}^{-} )}^{2} + {k}_{z}^{2}} )}{2} \qquad Eqn . ( 23 )$$

$$ϕ = ( {k}_{x}^{+} - {k}_{x}^{-} ) L = \frac{- 2 {m}^{*} {ν}_{0} {k}_{a v} L}{h \frac{( {k}_{x}^{+} + {k}_{x}^{-} )}{2}} \qquad Eqn . ( 24 )$$

In a TI material like Bi₂Se₃, small stress (or strain) can change the Dirac velocity v₀ along specific crystallographic directions by ˜2×10⁴ m/s per GPa of stress. Various embodiments include, without limitation, a particular utilization of this which provides a handle for an input voltage, e.g., via the FIG. 1 electrodes 110 connected to the piezoelectric layer 112 and layer 112's particular structure, corresponding inducement of strain, and its mechanical coupling to the TI body 102, vary the stress in the surface channel in a manner that correspondingly varies ϕ and hence the transmission probability T. Devices according to various embodiments therefore provide a voltage to current transfer characteristic through which the input voltage is a gate voltage that modulates a channel from a source contact to a drain contact, according to defined voltage to conductance characteristic, thereby realizing transistor action. Since such a transistor function comprises a 3D-TI body, strain, and spin interference—it is alternatively referenced as a strained topological insulator spin field effect transistor (STI-SPINFET).

### Numerical Results

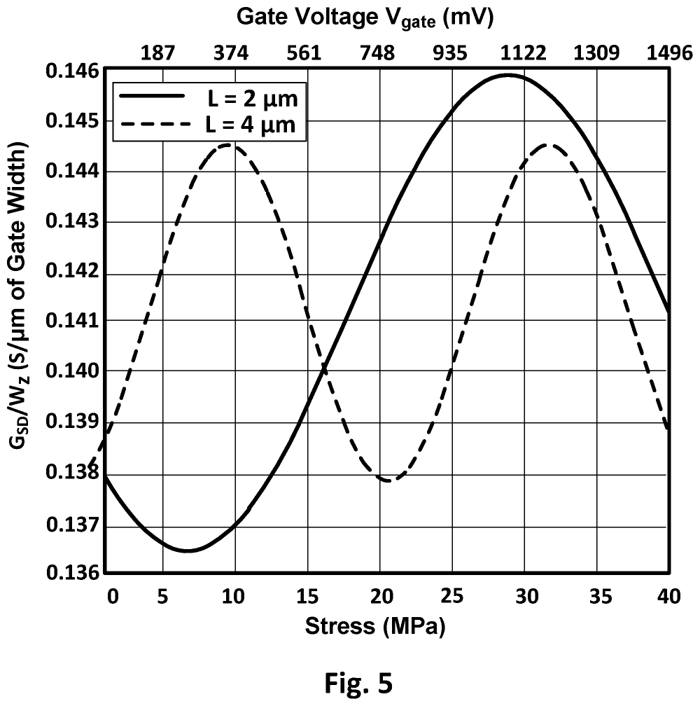

In FIG. 5, we plot the quantity

$$\frac{{G}_{S D}}{{W}_{Z}}$$

as a function of stress from 0 to 40 MPa in steps of 0.5 MPa.

The maximum pressure that we consider (40 MPa) is low enough that we can ignore all other pressure-related effects that can show up at extremely high pressures (several GPa). In the upper horizontal axis in FIG. 4, we plot the gate voltage V_{gate} needed to generate the corresponding stress. In this plot, we have assumed that the Fermi wave vector k_{F}=4×10¹⁰ m⁻¹, the effective mass m*=0.2 m₀ (where m₀ is the free electron mass), d₃₁=−670 pC/N, d=1 μm, and L=2000 and 4000 nm. This figure gives the transfer characteristic of the device.

### Voltage-to-Current Transfer Characteristic

PHOSITAs, upon reading this disclosure in its entirety and having possession of this disclosure can, in a manner according to such PHOSITAs' know-how, make, use, and sell products, devices, methods, and processes according to one or more embodiments, without undue experimentation. Such making, using, and selling may include, but does not require identification of closed form definition nor specification of an input-voltage-to-output current transfer characteristic. Such POSITAs can, in a manner according to such POSITAs know how, identify such a linear response channel conductance, or source-to-drain conductance, using the above written description and such written description with reference to the attached figures, and original appended claims.

For reader convenience and further assistance and/or acceleration of reader understanding of one or more features or aspects, one example derivation and example definition of such a transfer characteristic is presented below.

This derivation omits self-consistent effects, i.e., we will not invoke the Poisson equation because the surface of a TI is highly conductive. In a highly conductive channel (metallic), any effect of the Poisson equation (such as band bending) will be negligible and hence self-consistency effects can be safely ignored. We assume ballistic transport.

The current density in the channel between the source and the drain is given by the Tsu-Esaki formula, as Equation (26):

$${G}_{S D} = \frac{q}{{W}_{y}} {\int }_{0}^{∞} \frac{1}{h} d E \int \frac{d {k}_{z}}{π} T [ f ( {E}^{′} ) - f ( E + q {V}_{S D} ) ] , \qquad Eqn . ( 26 )$$

where q is the electron's charge, E is the electron (spin carrier) energy, Wy is the thickness of the channel in the y-direction (the vertical extent of the TI surface), V_{SD} is the applied source to drain voltage and f(ρ) is the Fermi-Dirac factor (electron occupation probability) at energy ρ in the source contact. This relation reduces to the Equation (27) form below

$${G}_{S D} = \frac{{q}^{2} {V}_{S D}}{{W}_{y}} {\int }_{0}^{∞} \frac{1}{h} d E \int \frac{d {k}_{z}}{π} T [ - \frac{\partial f ( E )}{\partial E} ] \qquad Eqn . ( 27 )$$

in the linear response regime when V_{SD}→0.

The channel conductance is therefore

$${G}_{S D} = \frac{{I}_{S D}}{{V}_{S D}} = \frac{{V}_{S D} {W}_{y} {W}_{z}}{{V}_{S D}} = \frac{{q}^{2} {W}_{z}}{π h} {\int }_{0}^{∞} d E \int d {k}_{z} T [ - \frac{\partial f ( E )}{\partial E} ] \qquad Eqn . ( 28 )$$

Assuming hypothetical “ideal” 3D-TI surface where the parabolic term in the Hamiltonian is absent this can be re-written according to Equation (29)

$${G}_{S D} = \frac{{q}^{2} {W}_{Z}}{π h} {\int }_{0}^{{k}_{F}} d {k}_{z} {cos}^{2} ( L \sqrt{{E ( \frac{{E}_{F}}{h {v}_{0}} )}^{2} - {k}_{Z}^{2}} ) \qquad Eqn . ( 29 )$$

This expression shows that changing the Dirac velocity v₀ with a gate voltage, changes the channel conductance (and hence the source-to-drain current for a fixed drain bias) with the gate voltage, thereby realizing transistor action.

Regarding the period of the voltage to current transfer characteristic, as can be seen in FIG. 5, in the gate voltage range 0 to 1.5 V there are two nearly complete periods of the oscillation in the channel conductance. Hence, if we apply an ac gate voltage with a peak-to-zero amplitude of 1.5 V, the source to drain current (for a fixed drain bias V_{SD}) will oscillate with a frequency four times that of the gate voltage. This can implement a frequency multiplier with a single transistor. In general, the frequency multiplication factor, M, will be according to the Equation (30).

$$M = 2 ( \frac{{V}_{g a t e}^{ampl}}{{V}_{period}} ) , \qquad Eqn . ( 30 )$$

where

$${V}_{g a t e}^{ampl}$$

is the peak-to-zero amplitude of the gate voltage and is the, V_{period} which is in volts, period of the oscillation of the source to drain current characteristic, i.e., the channel conductance.

The energy dissipated in the frequency multiplication operation can be according to the following Equation (31):

$${C ( {V}_{g a t e}^{ampl} )}^{2} = C {M}^{2} {V}_{p e r i o d}^{2} \qquad Eqn . ( 31 )$$

where C is the gate capacitance associated with either of the two electrodes 110 in FIG. 1.

We have disclosed a novel transistor device whose channel is made of a topological insulator (TI) thin film deposited on a piezoelectric film. According to various embodiments, the source and the drain contacts are ferromagnetic. The piezoelectric is utilized to strain the topological insulator with a gate voltage, which varies the Dirac velocity to rotate spin in the transistor's channel. That allows control of the channel conductance with the gate voltage (because of the spin filtering action of the drain) to implement a transistor.

It is noted that, as used herein and in the appended claims, the singular forms “a”, “an”, and “the” include plural referents unless the context clearly dictates otherwise. It is further noted that the claims may be drafted to exclude any optional element. As such, this statement is intended to serve as support for the recitation in the claims of such exclusive terminology as “solely,” “only” and the like in connection with the recitation of claim elements, or use of a “negative” limitations, such as “wherein [a particular feature or element] is absent”, or “except for [a particular feature or element]”, or “wherein [a particular feature or element] is not present (included, etc.) . . . ”.

Where a range of values is provided, it is understood that each intervening value, to the tenth of the unit of the lower limit unless the context clearly dictates otherwise, between the upper and lower limit of that range and any other stated or intervening value in that stated range, is encompassed within the invention. The upper and lower limits of these smaller ranges may independently be included in the smaller ranges and are also encompassed within the invention, subject to any specifically excluded limit in the stated range. Where the stated range includes one, or both of the limits, ranges excluding either or both of those included limits are also included in the invention.

As will be apparent to those of skill in the art upon reading this disclosure, each of the individual embodiments described and illustrated herein has discrete components and features which may be readily separated from or combined with the features of any of the other several embodiments without departing from the scope or spirit of the present invention. Any recited method can be carried out in the order of events recited or in any other order which is logically possible.

The invention is further described by the following non-limiting examples which further illustrate the invention, and are not intended, nor should they be interpreted to, limit the scope of the invention.

We claim:

1. A single-transistor low-power frequency multiplier device, comprising
a three-dimensional (3D) topological insulator (TI) body, having a planar surface extending between a first edge and a second edge, the planar surface providing a conducting surface channel for spin-polarized current flow extending from the first edge to the second edge;
a piezoelectric element coupled to the 3D TI body and configured to exert, responsive to an input voltage, one or more mechanical forces on the 3D TI body in a manner producing a corresponding mechanical stress in the surface channel; and
a spin polarizer adjacent the first edge and a spin analyzer adjacent the second edge, mutually configured to produce, in response to respective biasing voltages, an electric field extending into the first edge, through the surface channel and out the second edge, wherein the spin polarizer is further configured to inject, based at least in part on the electric field, spin polarized electrons onto the planar surface, wherein:
the surface channel is further configured to:
conduct a flow, urged by the electric field, of the spin polarized electrons from the first edge to arrive at the second edge as arrival spin polarized electrons, and
rotate the spin polarization of the electrons, during the flow, via a mechanical stress generated in by the input voltage applied to the piezoelectric element, resulting in the arrival spin polarized electrons having a rotated plane of spin polarization, with the amount of rotation depending on the input voltage,
the spin analyzer is further configured to pass only a fraction of the arrival spin polarized electrons, with the fraction depending on the angle of rotation, as electric output current whose magnitude depends on the angle of rotation and hence the input voltage, resulting in the output current having an oscillatory dependence on the input voltage, in accordance with an oscillatory output current versus input voltage transfer characteristic,
the oscillatory output current versus input voltage transfer characteristic has a period, the period being a voltage difference between a first voltage level of the input voltage, at which the angle of rotation is a theta value, and a second voltage level of the input voltage, at which the angle of rotation is again the theta value,
in accordance with the oscillatory output current versus input voltage transfer characteristic, responsive to an oscillating input voltage, oscillating at an input frequency, having an amplitude equal to a difference between the first voltage and the second voltage, the output current oscillates, with a frequency higher than the input frequency, producing a frequency multiplication by a frequency multiplication factor, and
the frequency multiplication factor is twice the ratio of the amplitude of the input voltage to the period of the transfer characteristic.

2. The single-transistor ultralow-power frequency multiplier device of claim 1, wherein the 3D TI body and the piezoelectric element are further configured to receive a changeable amplitude input voltage, and to vary the frequency multiplication factor in response to changes in the amplitude.

3. The single-transistor ultralow-power frequency multiplier device of claim 1, wherein the piezoelectric element is a piezoelectric film, supported on a conductive substrate, and the device further comprises one or more conductive plates that are arranged on and electrically coupled to the piezoelectric film, configured to receive the input voltage, wherein the conductive substrate is configured to be coupled to a reference potential while the one or more conductive plates receive the input voltage.

4. The single-transistor ultralow-power frequency multiplier of claim 1, wherein:
the spin polarizer comprises a first ferromagnetic element, and
the spin analyzer comprises a second ferromagnetic element, polarized at an analyzer polarization angle, and the fraction corresponds to a projection of the rotation angle onto the analyzer polarization angle.

5. A strained topological insulator (STI) based oscillatory transfer characteristic voltage-to-current device, comprising
a three-dimensional (3D) topological insulator (TI) body, having a conducting surface channel that extends a length from a first edge to a second edge of a planar surface, providing for spin polarized electron flow, and having a stress-to-rotation (STR) characteristic that during the flow, responsive to a level of a mechanical stress, rotates the polarization plane of the spin polarized electrons;
a piezoelectric element coupled to the 3D TI body and configured to mechanically strain the 3D TI body, responsive to an input voltage, in a manner producing the mechanical stress at a stress level according to a voltage-to-stress (VTS) characteristic, providing a voltage-to-rotation (VTR) characteristic based on the VTS and the STR characteristics;
a spin polarizer adjacent the first edge and a spin analyzer adjacent the second edge, mutually configured to produce, responsive to respective biasing voltages, an electric field extending into the first edge, through the conducting surface channel and out the second edge, wherein:
the spin polarizer is further configured to inject, responsive to the electric field, spin polarized electrons onto the planar surface, initiating flow of the spin polarized electrons through the conducting surface channel to arrive at the second edge as arrival spin polarized electrons, the polarization plane of the arrival spin polarized electrons being rotated by a rotation angle ⊖ in accordance with the input voltage and the VTR characteristic,
the piezoelectric element and the 3D TI body are further mutually configured such that the VTR characteristic is oscillatory, rotating ⊖ more than one cycle in response to increasing the input voltage from a first level to a second level, and
the spin analyzer is further configured to pass only a fraction of the arrival spin polarized electrons, as an output current, the fraction and therefore the output current depending on ⊖, converting the oscillatory VTR characteristic to an oscillatory voltage-to-current (VTC) transfer characteristic.

6. The STI-TI based oscillatory transfer characteristic voltage-to-current device of claim 5, wherein the device, responsive to the input voltage being an oscillating input voltage oscillating at an input oscillating frequency, with a magnitude comprising oscillating between the first voltage and the second voltage, generates the output current in accordance with the oscillatory VTC characteristic as an oscillating output current having a frequency that is a frequency multiplication factor higher than the input oscillating frequency.

7. The STI-TI based oscillatory transfer characteristic voltage-to-current device of claim 5, further comprising a conductive substrate, wherein:
the piezoelectric element comprises a piezoelectric film that is arranged on the conductive substrate, has a film thickness and is poled in the direction of the film thickness, and
the 3D TI body comprises a TI layer that is disposed on the piezoelectric film, having a TI film thickness.

8. The STI-TI based oscillatory transfer characteristic voltage-to-current device of claim 7, further comprising one or more conductive plates that are arranged on and electrically coupled to the piezoelectric film, and are configured to receive the input voltage, and
the conductive substrate is configured to be coupled to a reference potential while the one or more conductive plates receive the input voltage.

9. The STI-TI based oscillatory transfer characteristic voltage-to-current device of claim 8, wherein the oscillatory VTC transfer characteristic has a period, the period being a voltage difference between a period start voltage and a period end voltage and, in response to increasing the input voltage from the period start voltage to the period end voltage, a projection of ⊖ onto the analyzer polarization has one cycle and the oscillatory VTC transfer characteristic correspondingly has one cycle.

10. The STI-TI based oscillatory transfer characteristic voltage-to-current device of claim 9, wherein the frequency multiplication factor is twice the ratio of the amplitude of the input voltage to the period of the oscillatory VTC transfer characteristic.

11. The STI-TI based oscillatory transfer characteristic voltage-to-current device of claim 5, wherein:
the spin polarizer comprises a first ferromagnetic element, polarized with a configuration producing an injected spin polarization, and
the spin analyzer comprises a second ferromagnetic element, configured with a second element surface and disposed on the 3D TI body in an arrangement wherein the second element surface faces the second edge of the planar surface and toward the first element surface.
